(19) United States
(12) Patent Application Publication
(10) Pub. No.: US 2012/0227785 A1
(43) Pub. Date: Sep. 13, 2012

(54) SOLAR BATTERY CELL, SOLAR BATTERY MODULE, METHOD OF MAKING SOLAR BATTERY CELL AND METHOD OF MAKING SOLAR BATTERY MODULE

(75) Inventors: Yasuo TSURUOKA, Chikusei-shi (JP); Kenzou Takemura, Chikusei-shi (JP); Masaki Fujii, Chikusei-shi (JP); Yusuke Asakawa, Chikusei-shi (JP)

(73) Assignee: HITACHI CHEMICAL COMPANY, LTD., Tokyo (JP)

(21) Appl. No.: 13/414,807

(22) Filed: Mar. 8, 2012

Related U.S. Application Data
(60) Provisional application No. 61/450,314, filed on Mar. 8, 2011.

(51) Int. Cl. H01L 31/05; H01L 31/18; H01L 31/0224

(52) U.S. Cl. 136/244; 136/256; 438/98; 438/73; 257/E31.124

(57) ABSTRACT

A solar battery cell and related methodology are provided which enable a TAB wire to be accurately connected to an intended position, thus allowing a possible increase in manufacturing costs to be suppressed. A solar battery cell includes a plurality of finger electrodes arranged on a light receiving surface of a photovoltaic substrate, and an alignment marking indicating a position where a TAB wire is to be connected to the finger electrodes via a conductive adhesive. The alignment marking has portions discontinuously provided on the light receiving surface along a line crossing two of the finger electrodes positioned nearest opposite ends of the light receiving surface.

### BACKGROUND OF THE INVENTION

### Field of the Invention

The present invention relates to a solar battery cell, a solar battery module, a method of making a solar battery cell and a method of making a solar battery module.

### Related Background Art

In recent years, much attention has been paid to solar batteries as means for solving increasingly serious global warming and fossil energy depletion problems. A solar battery is normally formed by connecting a plurality of solar battery cells together in series or parallel. The solar battery cell includes a plurality of linear electrodes (finger electrodes) arranged in parallel on a front surface (light receiving surface) thereof and formed of Ag in order to provide power. A back surface electrode formed of Al is formed all over a back surface of the solar battery cell. Then, adjacent solar battery cells are connected together by connecting a metal wiring member (TAB wire) to the light receiving surface of one of the adjacent solar battery cells so that the metal wiring member crosses the all the finger electrodes and further connecting the TAB wire to the back surface electrode of the other solar battery cell.

Solder exhibiting proper conductivity is conventionally used to connect the TAB wire (Japanese Patent Laid-Open No. 2002-263880). Furthermore, in some cases, Sn—Ag—Cu solder, which contains no Pb, has recently been used with environmental problems taken into account (Japanese Patent Laid-Open Nos. 2002-263880 and 2004-204256). However, when these solders are used to connect the TAB wire, the solar battery cells are heated at about 220° C. or higher. Thus, the yield of the connection step may decrease or the solar battery cells may be warped. To suppress this, silicon in the solar battery cells may be increased in thickness. However, in this case, manufacturing costs increase.

Furthermore, when such solder as described is used to connect the TAB wire, the following measure needs to be taken in order to ensure wettability of the solder: electrodes (bus bar electrodes) formed of Ag is preformed on the front and back surfaces of the solar battery cell at the positions where the TAB wires are located. However, Ag is expensive, thus contributing to increasing costs. Additionally, Ag offers high electric resistance, and thin bus bar electrodes thus offer high sheet resistance. This increases power loss, thereby reducing the power generation performance of the solar battery cells. Thus, to suppress the sheet resistance of the bus bar electrodes, the bus bar electrodes need to be increased in width to some degree. This further increases the manufacturing costs.

Hence, in recent years, a method has been proposed in which a conductive adhesive with a conductive adhesion layer is used instead of the solder to connect the TAB wire (Japanese Patent Laid-Open Nos. 8-330615, 2003-133570, 2005-243935, and 2007-265635). The conductive adhesive is a thermosetting resin in which metal particles such as Al particles are mixed and dispersed. The metal particles are sandwiched between the TAB wire and the electrode of the solar battery cell to achieve electric connection. If the conductive adhesive is used to connect the TAB wire, the connection can be carried out at 200° C. or lower. This suppresses a decrease in the yield of the connection step and the warpage of the solar battery cells. Furthermore, if the conductive adhesive is used to connect the TAB wire, the wettability need not be ensured. This in turn eliminates the need for the bus bar electrodes, formed to ensure the wettability, thus reducing the use of Ag.

However, avoidance of formation of bus bar electrodes on the front or back surface of the solar battery cell prevents identification of the position where the TAB wires are connected. This may preclude the TAB wires from being accurately stuck to intended positions. When the TAB wires fail to be stuck to the intended positions, the lines of the solar battery cells may meander. Then, a residual stress may be generated in the solar battery cells, and the manufacturing yield may decrease.

The present invention has been made to solve the above-described problems. An object of the present invention is to provide a solar battery cell that enables the TAB wire to be accurately connected to the intended position, while allowing a possible increase in manufacturing costs to be suppressed.

### SUMMARY OF THE INVENTION

According to one of its broad concepts, the invention provides a solar battery cell, including a plurality of finger electrodes arranged on a light receiving surface of a photovoltaic substrate, and an alignment marking indicating a position where a TAB wire is to be connected to the finger electrodes via a conductive adhesive, the alignment marking having portions discontinuously provided on the light receiving surface along a line crossing two of the finger electrodes positioned nearest opposite ends of the light receiving surface.

In one of its aspects, the present invention provides a solar battery cell including a plurality of finger electrodes arranged on a light receiving surface and a TAB wire connected to the finger electrodes via a conductive adhesive, the solar battery cell including an alignment marking (also referred to throughout the specification as an alignment mark or marks) indicating a position where the TAB wire is connected to the finger electrodes, the alignment mark being discontinuously provided on the light receiving surface along a line crossing the finger electrodes positioned at opposite ends of the light receiving surface, the alignment mark being formed integrally with the finger electrodes using a material identical to a material of the finger electrodes in such a manner that the alignment mark has a line width equal to or smaller than a line width of the TAB wire to be connected to the finger electrodes.

In the solar battery cell according to the present invention, the alignment mark indicative of the position where the TAB wire is connected to the finger electrodes is provided along the line crossing the finger electrodes positioned at the opposite ends of the light receiving surface. Thus, checking the alignment mark allows the TAB wire connection position to be visually identified. Hence, the TAB wire can be accurately connected to an intended position. Furthermore, the alignment mark is formed integrally with the finger electrodes using the material identical to that of the finger electrodes. This allows the alignment mark to be easily formed simultaneously with formation of the finger electrodes. In addition, the alignment mark is discontinuously formed along the above-described line, and have a line width equal to or smaller than that of the TAB wire to be connected to the finger electrodes. Therefore, compared to the conventional solar battery cell with a continuous bus bar formed therein and having a width similar to that of the TAB wire, the solar battery cell according to the present invention serves to suppress a possible increase in the usage of the electrode material. As a result, a possible increase in manufacturing costs can be restrained.

Here, the alignment mark is preferably shaped like a dashed line. This not only allows a possible increase in the usage of the electrode material to be suppressed but also ensures visual identification.

Furthermore, each portion of the alignment mark preferably strides across a plurality of the finger electrodes. Then, when the finger electrodes are inspected for performance, the number of probes for the inspection can be reduced. This enables a reduction in inspection costs.

Additionally, a plurality of the alignment marks are preferably provided for one line. This allows the alignment marks to be more easily visually identified, allowing the TAB wire to be accurately connected to the intended position.

In addition, the plurality of alignment marks provided for the one line are preferably staggered with respect to each other. This allows the alignment marks to be more easily visually identified, allowing the TAB wire to be accurately connected to the intended position.

In addition, the plurality of alignment marks provided for the one line are preferably equal to or greater than the conductive adhesive in width. Then, the conductive adhesive may be applied to between the plurality of alignment marks so that the alignment marks can be visually identified after the application of the adhesive. Hence, the TAB wire can be more accurately connected to the intended position.

Furthermore, each portion of the alignment mark is preferably equal to or smaller than the finger electrode in line width. This enables a possible increase in the usage of the electrode material to be further suppressed. As a result, a possible increase in manufacturing costs can be restrained.

Additionally, each portion of the alignment mark is preferably at least 0.05 mm and at most 0.2 mm in line width. This enables a possible increase in the usage of the electrode material to be further suppressed. As a result, a possible increase in manufacturing costs can be restrained.

Furthermore, a solar battery module according to the present invention includes a plurality of the above-described solar battery cells arranged therein so that finger electrodes of one of adjacent solar battery cells are connected to a back surface electrode formed on a back surface of another of the adjacent solar battery cells, by means of a TAB wire arranged along an alignment mark via a conductive adhesive. In the solar battery module according to the present invention, the TAB wire is accurately connected to an intended position, thus allowing an array of solar battery cells to be restrained from meandering. Thus, when a solar battery module is manufactured, a possible residual stress in the solar battery cells can be suppressed. Therefore, manufacturing yield can be improved.

More generally, a solar battery module of the invention includes a plurality of the solar battery cells of the invention as described above, wherein the TAB wire is positioned along the alignment marking on one of the plurality of solar battery cells and is connected to the finger electrodes of the one solar battery cell via the conductive adhesive, and the TAB wire is further connected to a back surface electrode formed on a back surface of another of the plurality of solar battery cells.

According to another of its broad concepts, the invention provides a method of making a solar battery cell, comprising: providing a photovoltaic substrate having a plurality of finger electrodes arranged on a light receiving surface thereof, the light receiving surface having a region of predetermined width to receive a conductive adhesive of a same width as the region, and providing, at or adjacent to the region, an alignment marking indicating a position where a TAB wire is to be connected to the finger electrodes via the conductive adhesive, the alignment marking having portions discontinuously provided on the light receiving surface along a line crossing two of the finger electrodes positioned nearest opposite ends of the light receiving surface, the alignment marking being provided either before or after the plurality of finger electrodes are formed on the light receiving surface.

The present invention thus provides a solar battery cell and related methodology which enable the TAB wire to be accurately connected to intended position, while allowing a possible increase in manufacturing costs to be suppressed.

### BRIEF DESCRIPTION OF THE DRAWINGS

FIG. 1 is a plan view showing a light receiving surface of a solar battery cell according to a first embodiment of the present invention;

FIG. 2 is a bottom view showing a back surface of the solar battery cell in FIG. 1;

FIG. 3 is a perspective view showing that a plurality of the solar battery cells in FIG. 1 are connected together;

FIG. 4 is a schematic side view of FIG. 3; and

FIG. 5 is a plan view showing a front surface of a solar battery cell according to a second embodiment of the present invention.

FIG. 6 is a plan view showing a front surface of a solar battery cell according to a third embodiment of the present invention.

FIG. 7 is a plan view showing a front surface of a solar battery cell according to a fourth embodiment of the present invention.

FIG. 8 is a plan view showing a front surface of a solar battery cell according to a fifth embodiment of the present invention.

FIG. 9 is a plan view showing a front surface of a solar battery cell according to a sixth embodiment of the present invention.

FIG. 10 is a plan view showing a front surface of a solar battery cell according to a seventh embodiment of the present invention.

FIG. 11 is a plan view showing a front surface of a solar battery cell according to an eighth embodiment of the present invention.

FIG. 12 is a plan view showing a front surface of a solar battery cell according to a ninth embodiment of the present invention.

FIG. 13 is a plan view showing a front surface of a solar battery cell according to a tenth embodiment of the present invention.

FIG. 14 is a plan view showing a front surface of a solar battery cell according to an eleventh embodiment of the present invention.

FIG. 15 is a plan view showing a front surface of a solar battery cell according to a twelfth embodiment of the present invention.

FIG. 16 is a plan view showing a front surface of a solar battery cell according to a thirteenth embodiment of the present invention.

FIG. 17 is a plan view showing a front surface of a solar battery cell according to a fourteenth embodiment of the present invention.

FIG. 18 is a plan view showing a front surface of a solar battery cell according to a fifteenth embodiment of the present invention.

FIG. 19 is a plan view showing a front surface of a solar battery cell according to a sixteenth embodiment of the present invention.

FIG. 20 is a plan view showing a front surface of a solar battery cell according to a seventeenth embodiment of the present invention.

FIG. 21 is a figure showing one example of the light receiving surface alignment mark in the form of dashed line.

### DESCRIPTION OF THE PREFERRED EMBODIMENTS

Preferred embodiments of a solar battery cell and a method for manufacturing the solar battery cell according to the present invention will be described below in detail with reference to the drawings. The same elements are denoted by the same reference numerals, and duplicate descriptions are omitted.

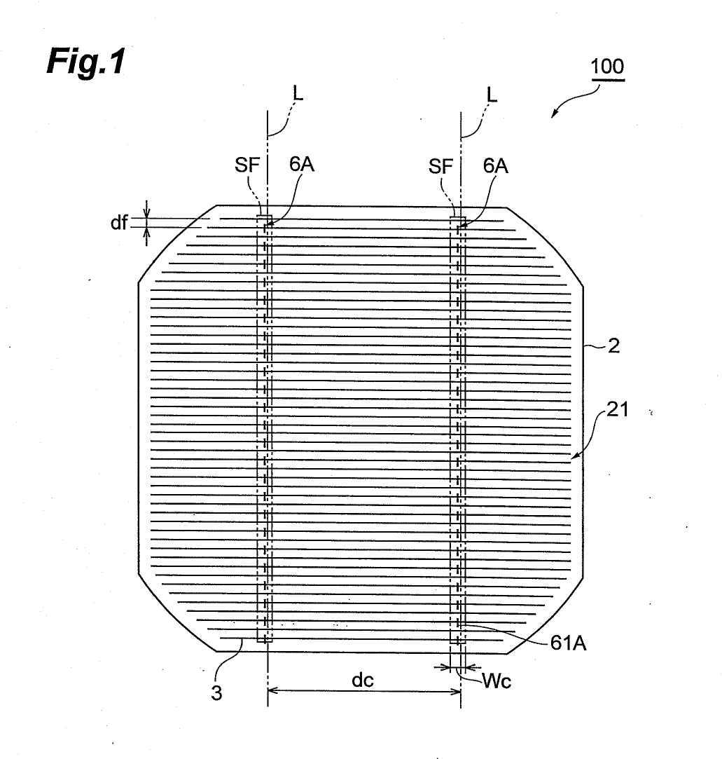

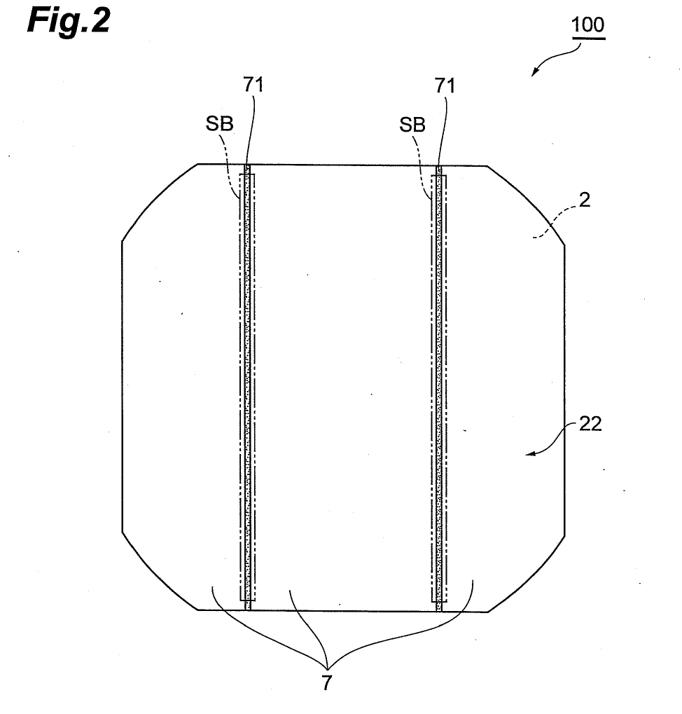

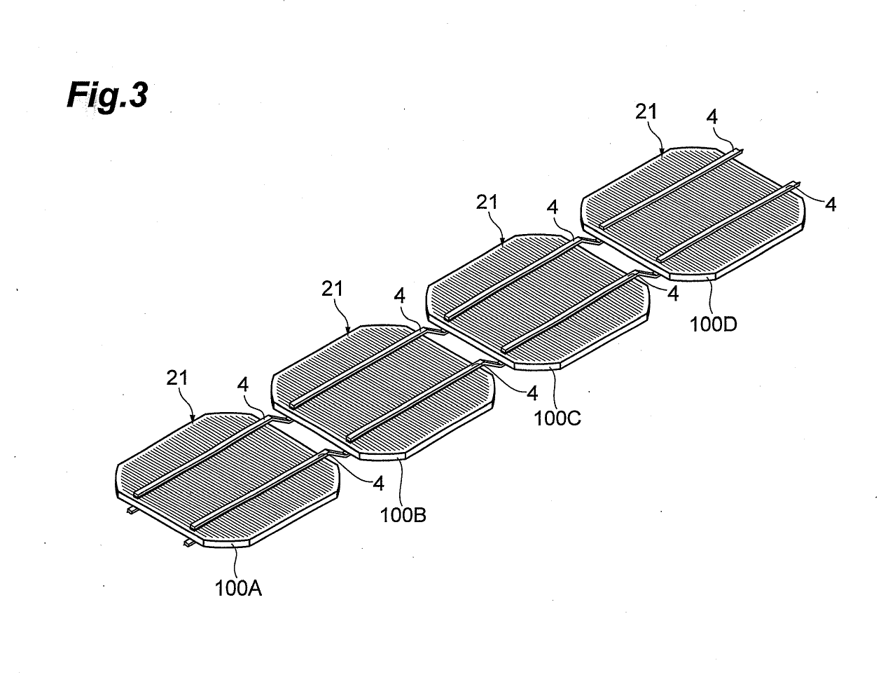

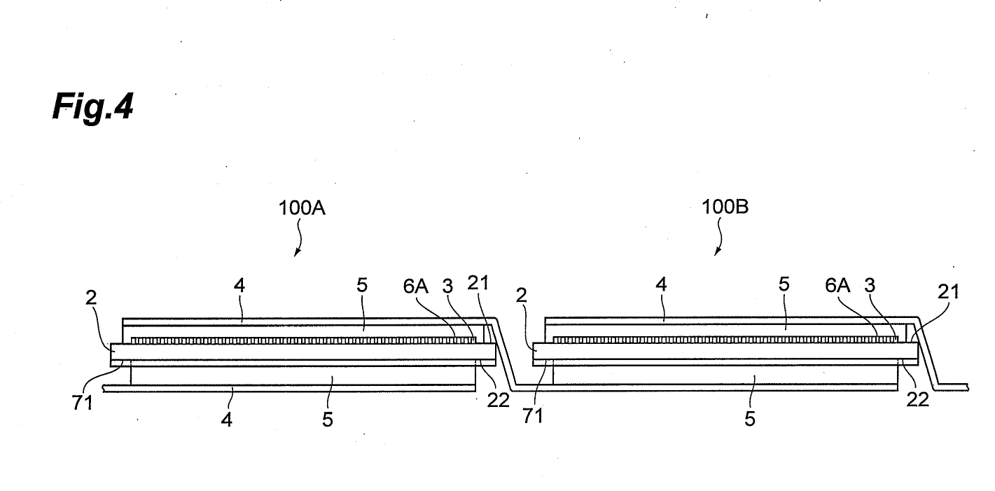

FIG. 1 is a plan view showing a light receiving surface of a solar battery cell according to a first embodiment of the present invention. FIG. 2 is a bottom view showing a back surface of the solar battery cell in FIG. 1. FIG. 3 is a perspective view showing that a plurality of the solar battery cells in FIG. 1 are connected together. FIG. 4 is a schematic side view of FIG. 3.

As shown in FIG. 1, a solar battery cell 100 is such that a plurality of the solar battery cells 100 are electrically connected together in series or parallel to form one solar battery module. The solar battery cell 100 includes a substrate 2. The substrate 2 is generally square and has four circular-arc corners. One surface of the substrate 2 corresponds to a light receiving surface 21. The other surface of the substrate 2 corresponds to a back surface 22 (see FIG. 2). The substrate 2 may be formed of at least one of a single crystal of Si, a polycrystal of Si, and a non-crystal of Si. On the light receiving surface 21 side, the substrate 2 may be formed of an n- or p-type semiconductor. On the substrate 2, for example, the distance between two opposite sides is 125 mm.

A plurality of (for example, 48) linear finger electrodes 3 are arranged on the light receiving surface 21 parallel to and away from one another. When a plurality of the solar battery cells 100 are connected together to form a solar battery module, TAB wires 4 are connected to the finger electrodes 3 via respective conductive adhesion films (conductive adhesives) 5 (see FIG. 4). Each of the finger electrodes 3 is, for example, 0.15 mm in line width. The distance df between the adjacent finger electrodes 3 is, for example, 2.55 mm.

Each of the finger electrodes 3 is formed of a known material providing electric continuity. Examples of the material of the finger electrode 3 include a glass paste containing silver; a silver paste, a gold paste, a carbon paste, a nickel paste, and an aluminum paste each containing an adhesive resin with one of the various types of conductive particles dispersed therein; and ITO formed by burning or deposition. Among these materials, the glass paste containing silver is preferably used in terms of heat resistance, electric conductivity, stability, and costs.

Adhesion areas SF, SF are areas of the light receiving surface 21 to which the respective conductive adhesion films 5, 5 are applied. The width we of the adhesion areas SF (that is, the width at the conductive adhesion films 5) is, for example, 1.2 mm. The distance dc between the adhesion areas SF, SF is, for example, 62 mm. Furthermore, the TAB wire 4, connected to the adhesion area SF, is, for example, 1.5 mm in width.

Light receiving surface alignment marks 6A, 6A are discontinuously provided on the light receiving surface 21 along a line

L so as to form dashed lines; the line L crosses the finger electrodes 3, 3 positioned at the opposite ends of the light receiving surface. More specifically, portions 61A of the light receiving surface alignment mark 6A each of which crosses only one finger electrode 3 are consecutively provided on every other finger electrode 3 along the line L. The light receiving surface alignment mark 6A is indicative of a position where the TAB wire 4 is connected to the finger electrodes 3. For example, the light receiving surface alignment mark 6A is arranged in a central portion of the adhesion area SF.

The light receiving surface alignment mark 6A is formed integrally with the finger electrodes 3 using the same material as that of the finger electrodes 3. That is, the light receiving surface alignment mark 6A is formed of a glass paste containing silver; a silver paste, a gold paste, a carbon paste, a nickel paste, or an aluminum paste containing an adhesive resin with one of the various types of conductive particles dispersed therein; or ITO formed by burning or deposition. Among these materials, the glass paste containing silver is preferably used in terms of heat resistance, electric conductivity, stability, and costs. The light receiving surface alignment marks 6A are formed simultaneously with formation of the finger electrodes 3.

Each portion 61A of the light receiving surface alignment mark 6A is at least 0.05 mm and at most 0.2 mm, for example, 0.15 mm in line width, similarly to the finger electrode 3 according to the present embodiment. That is, each portion 61A of the light receiving surface alignment mark 6A is equal to or smaller than the finger electrode 3 in line width. When the light receiving surface alignment mark 6A is at least 0.05 mm in line width, visual identification is ensured, allowing the light receiving surface alignment mark 6A to function as an alignment mark. Furthermore, when the light receiving surface alignment mark 6A is at most 0.2 mm in line width, the usage of the electrode material can be sufficiently reduced. Moreover, when the light receiving surface alignment mark 6A is equal to or smaller than the finger electrode 3 in line width, the usage of the electrode material can be further reduced. Alternatively, each portion 61A of the light receiving surface alignment mark 6A is preferably at most 20%, in line width, of the TAB wire to which the light receiving surface alignment mark 6A is connected. The distance between the light receiving surface alignment marks 6A, 6A is 62 mm similarly to the distance dc between the adhesion areas SF, SF.

As shown in FIG. 2, a back surface electrode 7 is formed all over a back surface 22 of the solar battery cell 100. When a plurality of solar battery cells 100 are connected together to form a solar battery module, the TAB wires 4 are connected to the back surface electrode 7 via the respective conductive adhesion films 5 (see FIG. 4). The back surface electrode 7 is formed by, for example, burning an aluminum paste.

Adhesion areas SB, SB indicate areas of the back surface 22 to which the conductive adhesion films 5 are applied. The positions of the adhesion areas SB, SB correspond to those of the adhesion areas SF on the light receiving surface 21. The width of the adhesion area SB is, for example, 1.2 mm like the width we of the adhesion area SF (see FIG. 1). The distance between the adhesion areas SB, SB is, for example, about 62 mm like the distance dc between the adhesion areas SF, SF (see FIG. 1). Furthermore, the width of the TAB wire 4 connected to the corresponding adhesion area SB is, for example, 1.5 mm like the width of the TAB wire connected to the light receiving surface 21.

Back surface alignment marks 71, 71 are provided on the back surface 22 along the respective adhesion areas SB so as to connect two opposite sides on the substrate 2. The back surface alignment mark 71 is indicative of the position where the corresponding TAB wire 4 is connected to the back surface electrode 7. For example, the back surface alignment mark 71 is located, for example, in a central portion of the adhesion area SB. The back surface alignment mark 71 is shaped like a groove. A part of the substrate 2 located under the back surface electrode 7 which part corresponds to the back surface alignment mark 71 is exposed from the back surface electrode 7 and is thus visible.

When the TAB wires 4 are connected to the back surface electrode 7 via the respective conductive adhesion films 5, the conductive adhesion films 5 need to be reliably in contact with the back surface electrode 7. Thus, the width of the back surface alignment mark 71 is smaller than that of the TAB wire 4 and is, for example, about 0.1 to 0.9 mm. The distance between the back surface alignment marks 71, 71 is, for example, 62 mm like the distance between the adhesion areas SB, SB.

As shown in FIG. 3, such solar battery cells 100 are arranged in a row so that the light receiving surface alignment marks 6A form a straight line, and coupled together by means of the TAB wires 4 which are arranged along the respective light receiving surface alignment marks 6A via the conductive adhesion films 5. The coupling is achieved by connecting the finger electrodes 3 on the light receiving surface 21 side of a solar battery cell 100A to the back surface electrode 7 on the back surface 22 side of a solar battery cell 100B adjacent to the solar battery cell 100A, by means of the corresponding TAB wires 4 (see FIG. 4), further connecting the finger electrodes 3 on the light receiving surface 21 side of the solar battery cell 100B to the back surface electrode 7 on the back surface 22 side of a solar battery cell 100C adjacent to the solar battery cell 100B, by means of the corresponding TAB wires, and repeating such operations. Thus, the plurality of solar battery cells 100 arranged in a line are electrically connected together in series. One or more such arrays are provided to form a solar battery module.

As described above, in the solar battery cell 100 according to the present embodiment, the light receiving surface alignment marks 6A, 6A indicative of the positions where the respective TAB wires 4 are connected to the finger electrodes 3 are provided along the respective lines L, L crossing the finger electrodes 3, 3 positioned at the opposite ends of the light receiving surface. Thus, checking the light receiving surface alignment marks 6A, 6A allows the connection positions for the TAB wires 4 to be visually identified. Hence, each of the TAB wires 4 can be accurately connected to an intended position.

Furthermore, in the solar battery cell 100, the light receiving surface alignment mark 6A is formed simultaneously with formation of the finger electrodes 3 and integrally with the finger electrodes 3 using the same material as that of the finger electrodes 3. Thus, the light receiving surface alignment mark 6A can be easily formed, allowing a possible increase in manufacturing costs to be suppressed.

Additionally, in the solar battery cell 100, the light receiving surface alignment mark 6A is discontinuously formed along the line L, and have a line width equal to or smaller than that of the TAB wire 4 to which the light receiving surface alignment mark 6A is connected. Thus, compared to the conventional solar battery cell with a continuous bus bar electrode formed therein and having a width similar to that of the TAB wire, the solar battery cell according to the present invention serves to suppress a possible increase in the usage of the electrode material. As a result, a possible increase in manufacturing costs can be restrained.

In addition, in the solar battery cell 100, the light receiving surface alignment mark 6A is shaped like a dashed line. This not only allows a possible increase in the usage of the electrode material to be suppressed but also ensures visual identification.

Furthermore, in the solar battery cell 100, each portion 61A of the light receiving surface alignment mark 6A is at least 0.05 mm and at most 0.2 mm in line width or is equal to or smaller than the finger electrode 3 in line width. This enables a possible increase in the usage of the electrode material to be further suppressed. As a result, a possible increase in manufacturing costs can be restrained.

Furthermore, in the solar battery module formed of the solar battery cells 100, a plurality of the solar battery cells 100 are arranged, and the finger electrodes 3 on one of the adjacent solar battery cells 100 are connected to the back surface electrode 7 formed on the back surface 22 of the other solar battery cell 100 by means of the respective TAB wires 4 arranged along the corresponding light receiving surface alignment marks 6A via the corresponding conductive adhesion films 5. In such a solar battery module, the TAB wires 4 are accurately connected to the intended positions, allowing the array of the solar battery cells 100 to be restrained from meandering. Thus, when a solar battery module is manufactured, a possible residual stress in the solar battery cells 100 can be suppressed, allowing manufacturing yield to be improved.

Now, a solar battery cell according to a second embodiment of the present invention will be described. The description of the present embodiment focuses on differences from the first embodiment.

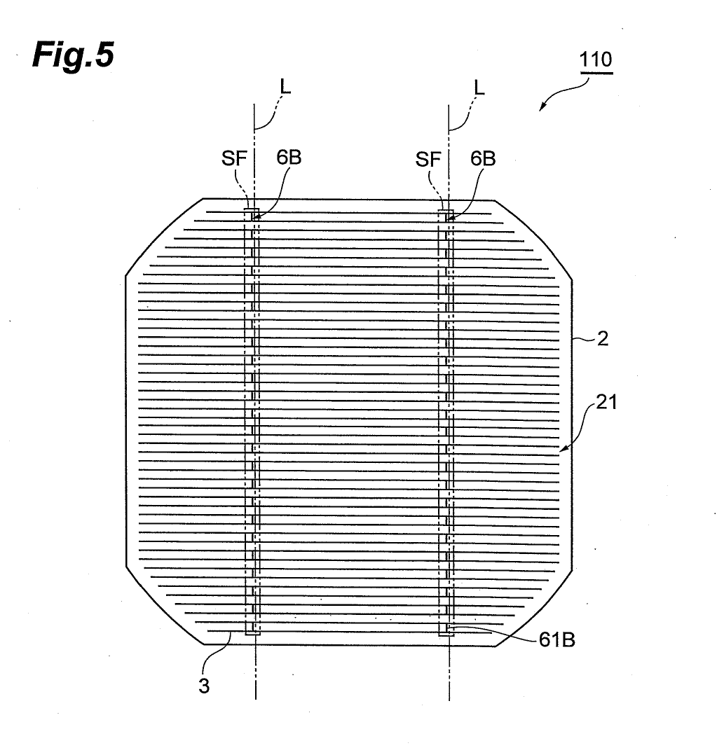

FIG. 5 is a plan view showing a front surface of a solar battery cell according to a second embodiment of the present invention. As shown in FIG. 5, a solar battery cell 110 according to the present embodiment is different from the solar battery cell 100 according to the first embodiment (see FIG. 1) in that the solar battery cell 110 includes light receiving surface alignment marks 6B different from the light receiving surface alignment marks 6A in the arrangement pattern of portions of the alignment mark.

The light receiving surface alignment mark 6B has a pattern in which portions 61B of the light receiving surface alignment mark 6B are consecutively arranged along the line L; each of the portions 61B strides across two adjacent finger electrodes 3, 3 so as to connect the finger electrodes 3, 3 together.

Of course, the solar battery cell 110 exerts effects similar to those of the solar battery cell 100 according to the first embodiment.

Furthermore, in the solar battery cell 110, each portion 61B of the light receiving surface alignment mark 6B strides across the two finger electrodes 3, 3. The thus configured light receiving surface alignment mark 6B contributes to simplifying the inspection of the finger electrodes 3 for disconnection or the like. That is, in such a configuration, the plurality of finger electrodes 3 across which each portion 61B of the light receiving surface alignment marks 6B strides form one mass. Thus, when an inspection probe comes into contact with the mass, the plurality of finger electrodes 3 can be inspected at a time. Hence, the number of probes required for the inspection can be reduced, enabling a reduction in inspection costs.

Now, a solar battery cell according to a third embodiment of the present invention will be described. Mainly differences of the present embodiment from the first embodiment will be described.

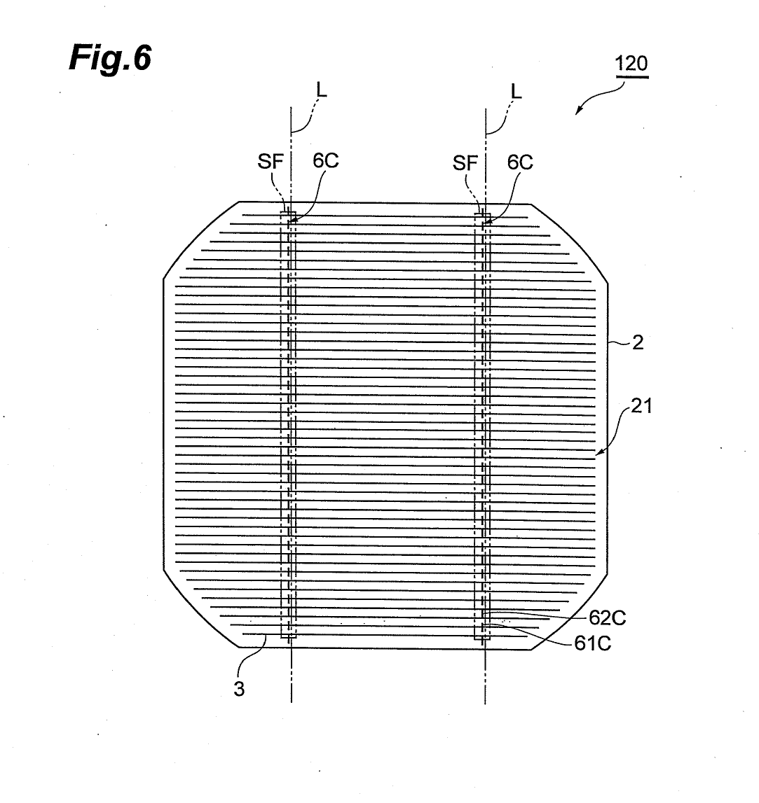

FIG. 6 is a plan view showing a front surface of the solar battery cell according to the third embodiment of the present invention. As shown in FIG. 6, a solar battery cell 120 according to the present embodiment is different from the solar battery cell 100 according to the first embodiment (see FIG. 1) in that the solar battery cell 120 includes light receiving surface alignment marks 6C different from the light receiving surface alignment marks 6A in the arrangement pattern of portions of the alignment mark.

The light receiving surface alignment mark 6C has a pattern in which portions 61C and portions 62C are alternately and consecutively arranged along the line L; each of the portions 61C crosses only one finger electrode 3, whereas each of the portions 62C strides across two adjacent finger electrodes 3, 3 so as to connect the finger electrodes 3, 3 together. Furthermore, the portions 62C, 62C are positioned outside the finger electrodes 3, 3 positioned at the opposite ends of the light receiving surface and each coupled to only one finger electrode 3.

Of course, the solar battery cell 120 configured as described above exerts effects similar to those of the solar battery cell 100 according to the first embodiment.

Furthermore, in the solar battery cell 120, each portion 62C of the light receiving surface alignment mark 6C strides across two finger electrodes 3, 3. The thus configured light receiving surface alignment mark 6C contributes to simplifying the inspection of the finger electrodes 3 for disconnection or the like. That is, in such a configuration, the plurality of finger electrodes 3 across which each portion 62C of the light receiving surface alignment marks 6C strides form one mass. Thus, when an inspection probe comes into contact with the mass, the plurality of finger electrodes 3 can be inspected at a time. Hence, the number of probes required for the inspection can be reduced, enabling a reduction in inspection costs.

Additionally, in the solar battery cell 120, the portions 62C, 62C are positioned outside the finger electrodes 3, 3 positioned at the opposite ends of the light receiving surface. Thus, when the conductive adhesion film 5 is applied to the solar battery cell 120, the portions 62C, 62C of the light receiving surface alignment mark 6C can be stuck out from the conductive adhesion film 5. As a result, whether or not the conductive adhesion film 5 has been applied to the intended position can be visually identified. This allows the TAB wire 4 to be more accurately connected to the intended position.

Now, a solar battery cell according to a fourth embodiment of the present invention will be described. Mainly differences of the present embodiment from the first embodiment will be described.

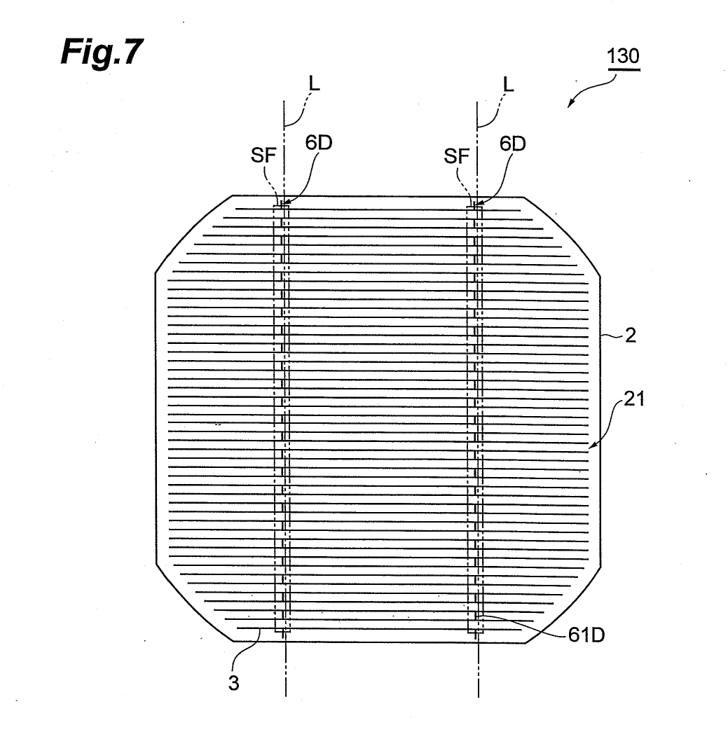

FIG. 7 is a plan view showing a front surface of the solar battery cell according to the fourth embodiment of the present invention. As shown in FIG. 7, a solar battery cell 130 according to the present embodiment is different from the solar battery cell 100 according to the first embodiment (see FIG. 1) in that the solar battery cell 130 includes light receiving surface alignment marks 6D different from the light receiving surface alignment marks 6A in the arrangement pattern of portions of the alignment mark.

The light receiving surface alignment mark 6D has a pattern in which portions 61D are consecutively arranged along the line L; each of the portions 61D strides across two adjacent finger electrodes 3, 3 so as to connect the finger electrodes 3, 3 together. Furthermore, the portions 61D, 61D are positioned outside the finger electrodes 3, 3 positioned at the opposite ends of the light receiving surface and each coupled to only one finger electrode 3.

Of course, the solar battery cell 130 configured as described above exerts effects similar to those of the solar battery cell 100 according to the first embodiment.

Furthermore, in the solar battery cell 130, each portion 61D of the light receiving surface alignment mark 6D strides across the two finger electrodes 3, 3. The thus configured light receiving surface alignment mark 6D contributes to simplifying the inspection of the finger electrodes 3 for disconnection or the like. That is, in such a configuration, the plurality of finger electrodes 3 across which each portion 61D of the light receiving surface alignment marks 6D strides form one mass. Thus, when an inspection probe comes into contact with the mass, the plurality of finger electrodes 3 can be inspected at a time. Hence, the number of probes required for the inspection can be reduced, enabling a reduction in inspection costs.

Additionally, in the solar battery cell 130, the portions 61D, 61D are positioned outside the finger electrodes 3, 3 positioned at the opposite ends of the light receiving surface. Thus, when the conductive adhesion film 5 is applied to the solar battery cell 130, the portions 61D, 61D of the light receiving surface alignment mark 6D can be stuck out from the conductive adhesion film 5. As a result, whether or not the conductive adhesion film 5 has been applied to the intended position can be visually identified. This allows the TAB wire 4 to be more accurately connected to the intended position.

Now, a solar battery cell according to a fifth embodiment of the present invention will be described. Mainly differences of the present embodiment from the first embodiment will be described.

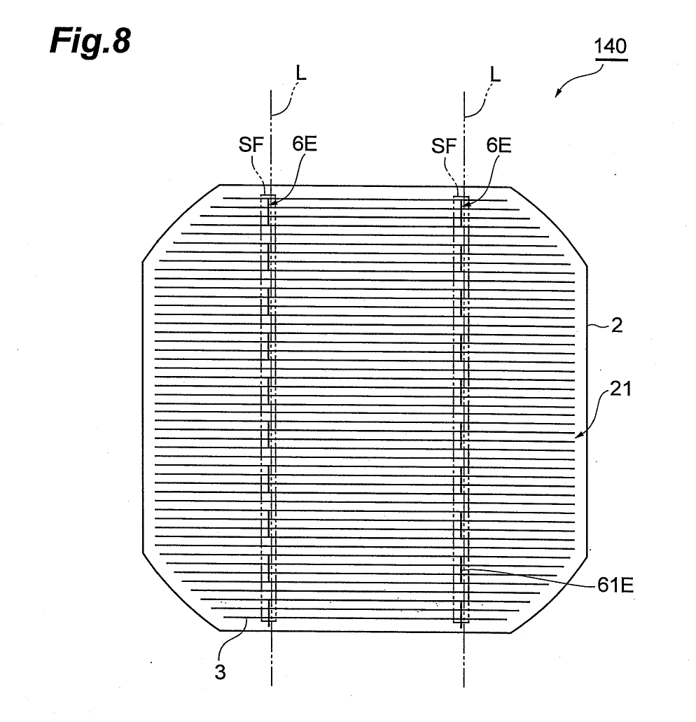

FIG. 8 is a plan view showing a front surface of the solar battery cell according to the fifth embodiment of the present invention. As shown in FIG. 8, a solar battery cell 140 according to the present embodiment is different from the solar battery cell 100 according to the first embodiment (see FIG. 1) in that the solar battery cell 140 includes light receiving surface alignment marks 6E different from the light receiving surface alignment marks 6A in the length and arrangement pattern of portions of the alignment mark.

The light receiving surface alignment mark 6E has a pattern in which portions 61E are consecutively arranged along the line L; each of the portions 61E strides across a set of four adjacent finger electrodes 3 to 3 so as to connect together two of the four finger electrodes 3 to 3 which are located at the opposite ends of the set. The portion 61E crossing the finger electrodes 3 positioned at a lower end of the light receiving surface strides across only three adjacent finger electrodes 3 to 3. Furthermore, one finger electrode 3 not coupled to any of the portions 61E is interposed between the consecutive portions 61E, 61E.

Of course, the solar battery cell 140 configured as described above exerts effects similar to those of the solar battery cell 100 according to the first embodiment.

Furthermore, in the solar battery cell 140, each portion 61E of the light receiving surface alignment mark 6E strides across the four finger electrodes 3, 3. The thus configured light receiving surface alignment mark 6E contributes to simplifying the inspection of the finger electrodes 3 for disconnection or the like. That is, in such a configuration, the plurality of finger electrodes 3 across which each portion 61E of the light receiving surface alignment marks 6E strides form one mass. Thus, when an inspection probe comes into contact with the mass, the plurality of finger electrodes 3 can be inspected at a time. Hence, the number of probes required for the inspection can be reduced, enabling a reduction in inspection costs.

Now, a solar battery cell according to a sixth embodiment of the present invention will be described. Mainly differences of the present embodiment from the first embodiment will be described.

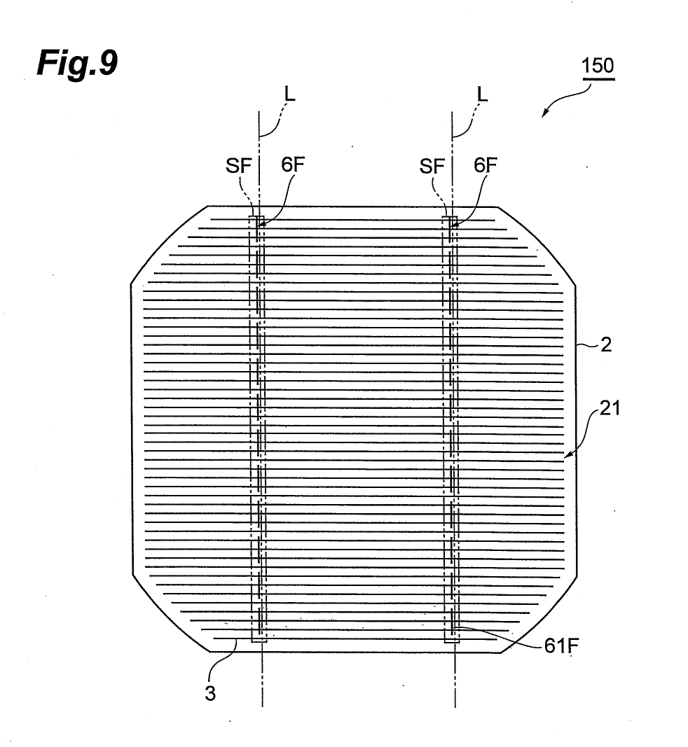

FIG. 9 is a plan view showing a front surface of the solar battery cell according to the sixth embodiment of the present invention. As shown in FIG. 9, a solar battery cell 150 according to the present embodiment is different from the solar battery cell 100 according to the first embodiment (see FIG. 1) in that the solar battery cell 150 includes light receiving surface alignment marks 6F different from the light receiving surface alignment marks 6A in the length and arrangement pattern of portions of the alignment mark.

The light receiving surface alignment mark 6F has a pattern in which portions 61F are consecutively arranged along the line L; each of the portions 61F strides across three adjacent finger electrodes 3 to 3 so as to connect the finger electrodes 3 to 3 together. One finger electrode 3 not coupled to any of the portions 61F is interposed between the consecutive portions 61F, 61F.

Of course, the solar battery cell 150 configured as described above exerts effects similar to those of the solar battery cell 100 according to the first embodiment.

Furthermore, in the solar battery cell 150, each portion 61F of the light receiving surface alignment mark 6F strides across the three finger electrodes 3 to 3. The thus configured light receiving surface alignment mark 6F contributes to simplifying the inspection of the finger electrodes 3 for disconnection or the like. That is, in such a configuration, the plurality of finger electrodes 3 across which each portion 61F of the light receiving surface alignment marks 6F strides form one mass. Thus, when an inspection probe comes into contact with the mass, the plurality of finger electrodes 3 can be inspected at a time. Hence, the number of probes required for the inspection can be reduced, enabling a reduction in inspection costs.

Now, a solar battery cell according to a seventh embodiment of the present invention will be described. Mainly differences of the present embodiment from the first embodiment will be described.

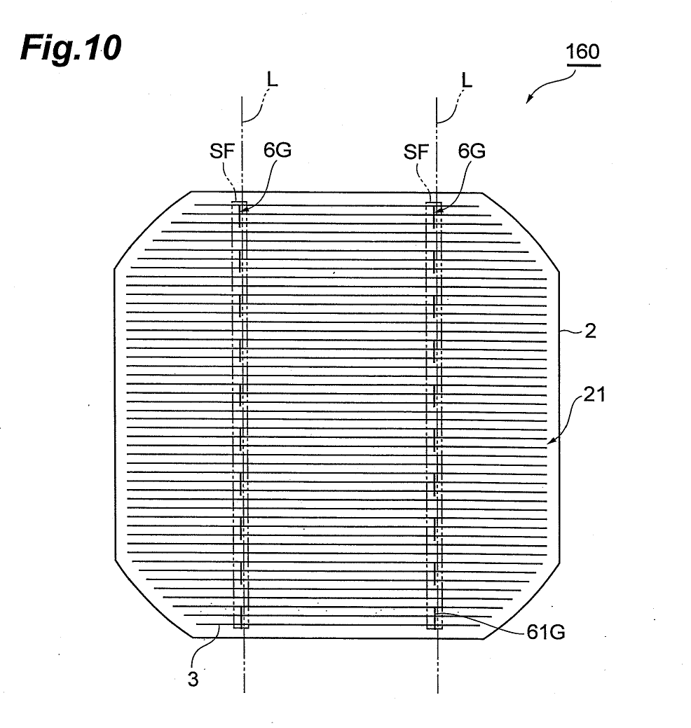

FIG. 10 is a plan view showing a front surface of the solar battery cell according to the seventh embodiment of the present invention. As shown in FIG. 10, a solar battery cell 160 according to the present embodiment is different from the solar battery cell 100 according to the first embodiment (see FIG. 1) in that the solar battery cell 160 includes light receiving surface alignment marks 6G different from the light receiving surface alignment marks 6A in the length and arrangement pattern of portions of the alignment mark.

The light receiving surface alignment mark 6G has a pattern in which portions 61G are consecutively arranged along the line L; each of the portions 61G strides across a set of three adjacent finger electrodes 3 to 3 so as to connect together two of the three finger electrodes 3 to 3 which are located at the opposite ends of the set. The lower end of each portion 61G projects from the set of the three adjacent finger electrodes 3. Furthermore, two finger electrodes 3 not coupled to any of the portions 61 G are interposed between the consecutive portions 61G, 61G.

Of course, the solar battery cell 160 configured as described above exerts effects similar to those of the solar battery cell 100 according to the first embodiment.

Furthermore, in the solar battery cell 160, each portion 61G of the light receiving surface alignment mark 6G strides across the three finger electrodes 3 to 3. The thus configured light receiving surface alignment mark 6G contributes to simplifying the inspection of the finger electrodes 3 for disconnection or the like. That is, in such a configuration, the plurality of finger electrodes 3 across which each portion 61 G of the light receiving surface alignment marks 6G strides form one mass. Thus, when an inspection probe comes into contact with the mass, the plurality of finger electrodes 3 can be inspected at a time. Hence, the number of probes required for the inspection can be reduced, enabling a reduction in inspection costs.

Now, a solar battery cell according to an eighth embodiment of the present invention will be described. Mainly differences of the present embodiment from the first embodiment will be described.

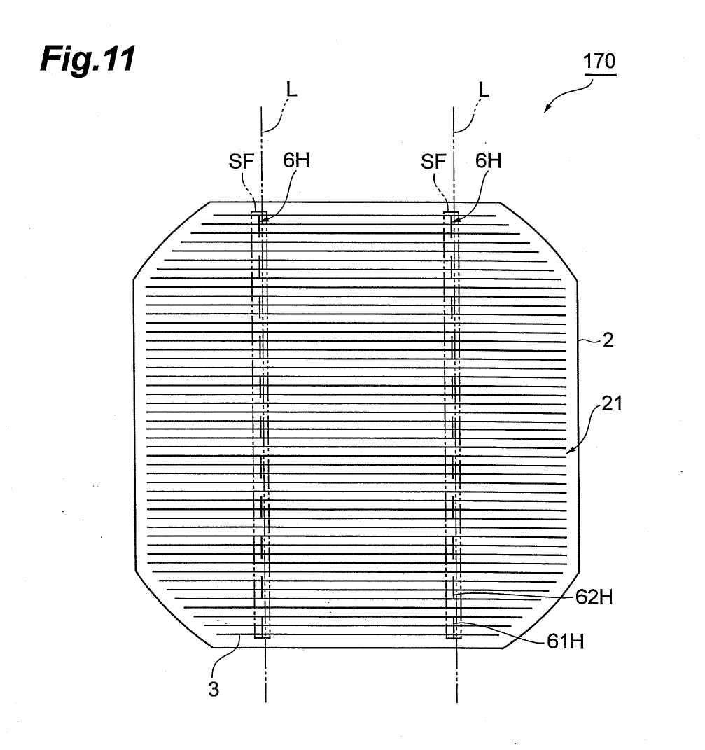

FIG. 11 is a plan view showing a front surface of the solar battery cell according to the eighth embodiment of the present invention. As shown in FIG. 11, a solar battery cell 170 according to the present embodiment is different from the solar battery cell 100 according to the first embodiment (see FIG. 1) in that the solar battery cell 170 includes light receiving surface alignment marks 6H different from the light receiving surface alignment marks 6A in the length and arrangement pattern of portions of the alignment mark.

The light receiving surface alignment mark 6H has a pattern in which portions 61H and portions 62H are consecutively arranged along the line L; each of the portions 61H strides across a set of three adjacent finger electrodes 3 to 3 so as to connect together two of the three finger electrodes 3 to 3 which are located at the opposite ends of the set, with the lower end of each portion 61H projecting from the set of the three finger electrodes 3, 3 and each of the portions 62H strides across a set of three adjacent finger electrodes 3 to 3 so as to connect together two of the three finger electrodes 3 to 3 which are located at the opposite ends of the set, with the upper end of each portion 62H projecting from the set of the three finger electrodes 3, 3. Furthermore, two finger electrodes 3 not coupled to any of the portions 61H and 62H are interposed between the consecutive portions 61H and 62H.

Of course, the solar battery cell 170 configured as described above exerts effects similar to those of the solar battery cell 100 according to the first embodiment.

Furthermore, in the solar battery cell 170, each of the portions 61H and 62H of the light receiving surface alignment mark 6H strides across the three finger electrodes 3 to 3. The thus configured light receiving surface alignment mark 6H contributes to simplifying the inspection of the finger electrodes 3 for disconnection or the like. That is, in such a configuration, the plurality of finger electrodes 3 across which each of the portions 61H and 62H of the light receiving surface alignment marks 6H strides form one mass. Thus, when an inspection probe comes into contact with the mass, the plurality of finger electrodes 3 can be inspected at a time. Hence, the number of probes required for the inspection can be reduced, enabling a reduction in inspection costs.

Now, a solar battery cell according to a ninth embodiment of the present invention will be described. Mainly differences of the present embodiment from the first embodiment will be described.

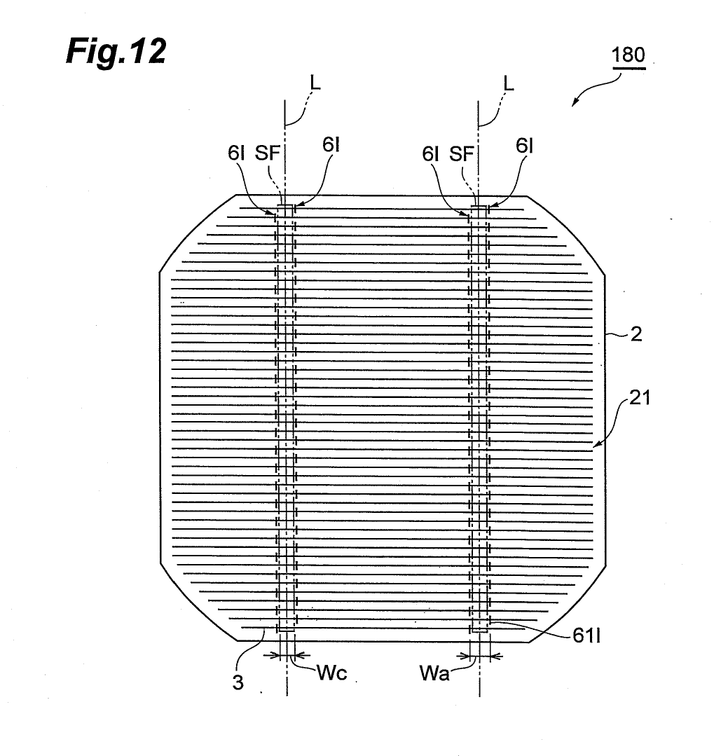

FIG. 12 is a plan view showing a front surface of the solar battery cell according to the ninth embodiment of the present invention. As shown in FIG. 12, a solar battery cell 180 according to the present embodiment is different from the solar battery cell 100 according to the first embodiment (see FIG. 1) in that a plurality of light receiving surface alignment marks 61 are provided for one line L.

A plurality of (for example, two) light receiving surface alignment marks 61 are provided for one line L. For example, the light receiving surface alignment marks 61 are provided on the right and left, respectively, of the line L. The width Wa between the light receiving surface alignment marks 61 and 61 is equal to or greater than the width We of the adhesion area SF (that is, the width of the conductive adhesion film 5). The light receiving surface alignment mark 61 has a pattern in which portions 611 of the light receiving surface alignment mark 61 crossing only one finger electrode 3 are consecutively provided on every other finger electrode 3 along the line L. Furthermore, in the light receiving surface alignment marks 61 and 61 provided on the right and left, respectively, of the line L, the portions 611 of one of the light receiving surface alignment marks 61 are staggered with respect to the portions 611 of the other light receiving surface alignment mark 61. Thus, the light receiving surface alignment marks 61 and 61 are staggered with respect to each other.

Of course, the solar battery cell 180 configured as described above exerts effects similar to those of the solar battery cell 100 according to the first embodiment.

Furthermore, in the solar battery cell 180, since the plurality of (for example, two) light receiving surface alignment marks 61 are provided for the one line L, the alignment marks can be more easily visually identified, allowing the TAB wire 4 to be accurately connected to the intended position.

Additionally, in the solar battery cell 180, the width Wa between the plurality of (for example, two) light receiving surface alignment marks 61, 61 provided for the one line L is equal to or greater than the width We of the conductive adhesion film 5. Thus, the conductive adhesion film 5 may be applied to between the light receiving surface alignment marks 61 and 61 so that the light receiving surface alignment marks 61, 61 can be visually identified after the application of the conductive adhesion film 5. Hence, the TAB wire 4 can be more accurately connected to the intended position.

In addition, in the solar battery cell 180, the plurality of light receiving surface alignment marks 61 and 61 provided for the one line L are staggered with respect to each other. Thus, the alignment marks can be more easily visually identified, allowing the TAB wire 4 to be accurately connected to the intended position.

Now, a solar battery cell according to a tenth embodiment of the present invention will be described. Mainly differences of the present embodiment from the first embodiment will be described.

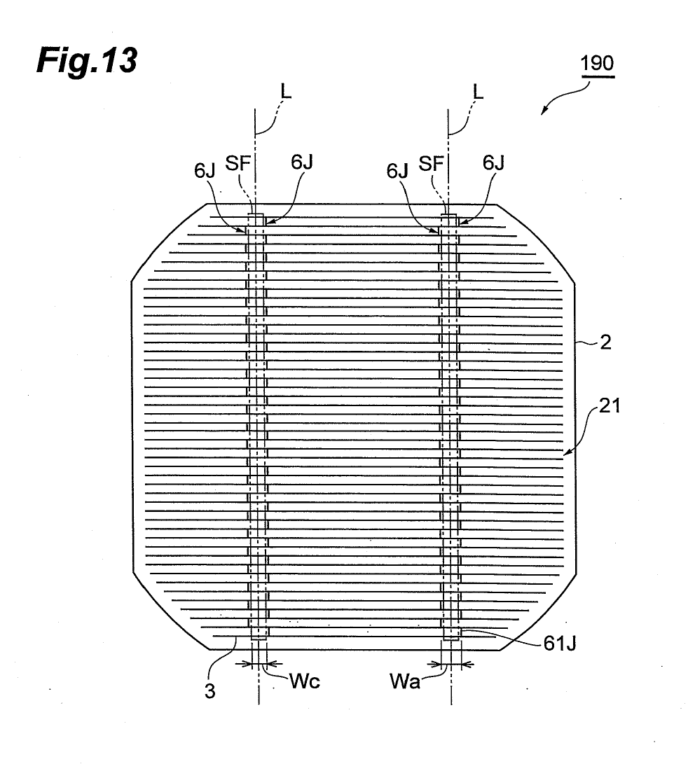

FIG. 13 is a plan view showing a front surface of the solar battery cell according to the tenth embodiment of the present invention. As shown in FIG. 13, a solar battery cell 190 according to the present embodiment is different from the solar battery cell 100 according to the first embodiment (see FIG. 1) in that a plurality of light receiving surface alignment marks 6J are provided for one line L; each of the light receiving surface alignment marks 6J is different from the light receiving surface alignment mark 6A in the arrangement pattern of portions of the alignment mark.

A plurality of (for example, two) light receiving surface alignment marks 6J are provided for one line L. For example, the light receiving surface alignment marks 6J are provided on the right and left, respectively, of the line L. The width Wa between the light receiving surface alignment marks 6J and 6J is equal to or greater than the width We of the adhesion area SF (that is, the width of the conductive adhesion film 5). The light receiving surface alignment mark 6J has a pattern in which portions 61J of the light receiving surface alignment mark 6J are consecutively arranged along the line L; each of the portions 61J strides across two adjacent finger electrodes 3, 3 so as to connect the finger electrodes 3, 3 together. Furthermore, in the light receiving surface alignment marks 6J and 6J provided on the right and left, respectively, of the line L, the portions 61J of one of the light receiving surface alignment marks 6J are staggered with respect to the portions 61J of the other light receiving surface alignment mark 6J. Thus, the light receiving surface alignment marks 6J and 6J are staggered with respect to each other. Additionally, since the portions 61J each striding across the two adjacent finger electrodes 3, 3 are arranged in a staggered manner, all the finger electrodes 3 are coupled together by the light receiving surface alignment marks 6J, 6J.

Of course, the solar battery cell 190 configured as described above exerts effects similar to those of the solar battery cell 100 according to the first embodiment.

Furthermore, in the solar battery cell 190, since the plurality of (for example, two) light receiving surface alignment marks 6J are provided for the one line L, the alignment marks can be more easily visually identified, allowing the TAB wire 4 to be accurately connected to the intended position.

Additionally, in the solar battery cell 190, the width Wa between the plurality of (for example, two) light receiving surface alignment marks 6J, 6J provided for the one line L is equal to or greater than the width We of the conductive adhesion film 5. Thus, the conductive adhesion film 5 may be applied to between the light receiving surface alignment marks 6J and 6J so that the light receiving surface alignment marks 6J, 6J can be visually identified after the application of the conductive adhesion film 5. Hence, the TAB wire 4 can be more accurately connected to the intended position.

In addition, in the solar battery cell 190, the plurality of light receiving surface alignment marks 6J and 6J provided for the one line L are staggered with respect to each other. Thus, the alignment marks can be more easily visually identified, allowing the TAB wire 4 to be accurately connected to the intended position.

Furthermore, in the solar battery cell 190, since the portions 61J each striding across the two adjacent finger electrodes 3, 3 are arranged in a staggered manner, all the finger electrodes 3 are coupled together by the light receiving surface alignment marks 6J, 6J. The thus configured light receiving surface alignment mark 6J contributes to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to an eleventh embodiment of the present invention will be described. Mainly differences of the present embodiment from the first embodiment will be described.

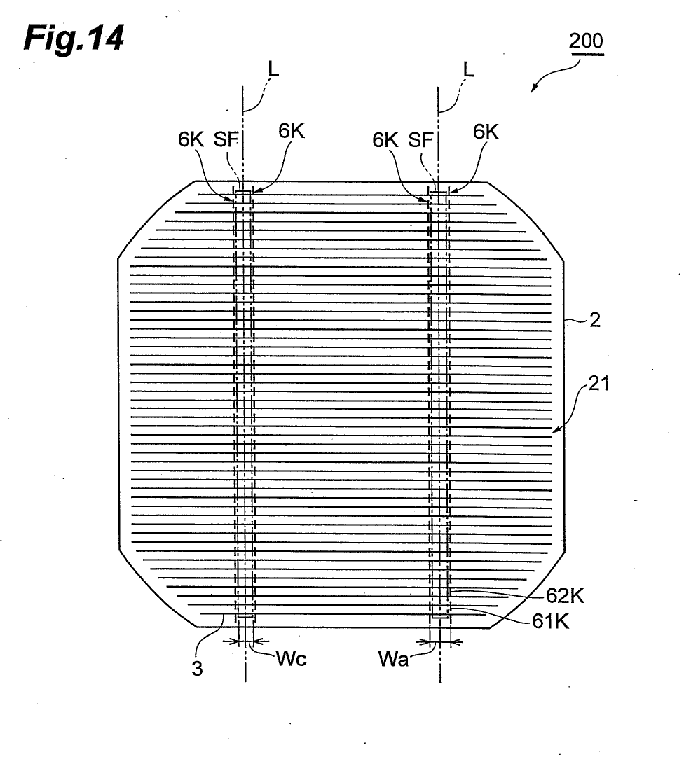

FIG. 14 is a plan view showing a front surface of the solar battery cell according to the eleventh embodiment of the present invention. As shown in FIG. 14, a solar battery cell 200 according to the present embodiment is different from the solar battery cell 100 according to the first embodiment (see FIG. 1) in that a plurality of light receiving surface alignment marks 6K are provided for one line L; each of the light receiving surface alignment marks 6K is different from the light receiving surface alignment mark 6A in the arrangement pattern of portions of the alignment mark.

A plurality of (for example, two) light receiving surface alignment marks 6K are provided for one line L. For example, the light receiving surface alignment marks 6K are provided on the right and left, respectively, of the line L. The width Wa between the light receiving surface alignment marks 6K and 6K is equal to or greater than the width We of the adhesion area SF (that is, the width of the conductive adhesion film 5). The light receiving surface alignment mark 6K has a pattern in which portions 61K and portions 62K are alternately and consecutively arranged along the line L; each of the portions 61K crosses only one finger electrode 3, whereas each of the portions 62K strides across two adjacent finger electrodes 3, 3 so as to connect the finger electrodes 3, 3 together.

Of course, the solar battery cell 200 configured as described above exerts effects similar to those of the solar battery cell 100 according to the first embodiment.

Furthermore, in the solar battery cell 200, each portion 62K of the light receiving surface alignment mark 6K strides across the two finger electrodes 3, 3. The thus configured light receiving surface alignment mark 6K contributes to simplifying the inspection of the finger electrodes 3 for disconnection or the like. That is, in such a configuration, the plurality of finger electrodes 3 across which each of the portion 62K of the light receiving surface alignment marks 6K strides form one mass. Thus, when an inspection probe comes into contact with the mass, the plurality of finger electrodes 3 can be inspected at a time. Hence, the number of probes required for the inspection can be reduced, enabling a reduction in inspection costs.

Additionally, in the solar battery cell 200, since the plurality of (for example, two) light receiving surface alignment marks 6K are provided for the one line L, the alignment marks can be more easily visually identified, allowing the TAB wire 4 to be accurately connected to the intended position.

In addition, in the solar battery cell 200, the width Wa between the plurality of (for example, two) light receiving surface alignment marks 6K, 6K provided for the one line L is equal to or greater than the width We of the conductive adhesion film 5. Thus, the conductive adhesion film 5 may be applied to between the light receiving surface alignment marks 6K and 6K so that the light receiving surface alignment marks 6K, 6K can be visually identified after the application of the conductive adhesion film 5. Hence, the TAB wire 4 can be more accurately connected to the intended position.

Now, a solar battery cell according to a twelfth embodiment of the present invention will be described. Mainly differences of the present embodiment from the first embodiment will be described.

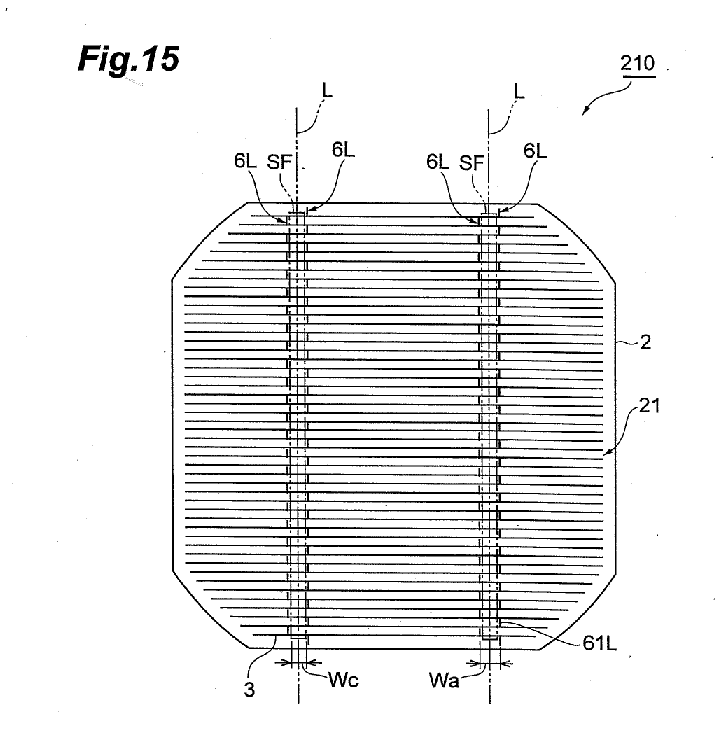

FIG. 15 is a plan view showing a front surface of the solar battery cell according to the twelfth embodiment of the present invention. As shown in FIG. 15, a solar battery cell 210 according to the present embodiment is different from the solar battery cell 100 according to the first embodiment (see FIG. 1) in that a plurality of light receiving surface alignment marks 6L are provided for one line L; each of the light receiving surface alignment marks 6L is different from the light receiving surface alignment mark 6A in the arrangement pattern of portions of the alignment mark.

A plurality of (for example, two) light receiving surface alignment marks 6L are provided for one line L. For example, the light receiving surface alignment marks 6L are provided on the right and left, respectively, of the line L. The width Wa between the light receiving surface alignment marks 6L and 6L is equal to or greater than the width We of the adhesion area SF (that is, the width of the conductive adhesion film 5). The light receiving surface alignment mark 6L has a pattern in which portions 61L of the light receiving surface alignment mark 6L are consecutively arranged along the line L; each of the portions 61L strides across two adjacent finger electrodes 3, 3 so as to connect the finger electrodes 3,3 together. Furthermore, in the light receiving surface alignment marks 6L and 6L provided on the right and left, respectively, of the line L, the portions 61L of one of the light receiving surface alignment marks 6L are staggered with respect to the portions 61L of the other light receiving surface alignment mark 6L. Thus, the light receiving surface alignment marks 6L and 6L are staggered with respect to each other. Additionally, since the portions 61L each striding across the two adjacent finger electrodes 3, 3 are arranged in a staggered manner, all the finger electrodes 3 are coupled together by the light receiving surface alignment marks 6L, 6L.

Of course, the solar battery cell 210 configured as described above exerts effects similar to those of the solar battery cell 100 according to the first embodiment.

Furthermore, in the solar battery cell 210, since the plurality of (for example, two) light receiving surface alignment marks 6L, 6L are provided for the one line L, the alignment marks can be more easily visually identified, allowing the TAB wire 4 to be accurately connected to the intended position.

Additionally, in the solar battery cell 210, the width Wa between the plurality of (for example, two) light receiving surface alignment marks 6L, 6L provided for the one line L is equal to or greater than the width We of the conductive adhesion film 5. Thus, the conductive adhesion film 5 may be applied to between the light receiving surface alignment marks 6L and 6L so that the light receiving surface alignment marks 6L, 6L can be visually identified after the application of the conductive adhesion film 5. Hence, the TAB wire 4 can be more accurately connected to the intended position.

In addition, in the solar battery cell 210, the plurality of light receiving surface alignment marks 6L and 6L provided for the one line L are staggered with respect to each other. Thus, the alignment marks can be more easily visually identified, allowing the TAB wire 4 to be accurately connected to the intended position.

Furthermore, in the solar battery cell 210, since the portions 61L each striding across the two adjacent finger electrodes 3, 3 are arranged in a staggered manner, all the finger electrodes 3 are coupled together by the light receiving surface alignment marks 6L, 6L. The thus configured light receiving surface alignment mark 6L contributes to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to a thirteenth embodiment of the present invention will be described. Mainly differences of the present embodiment from the first embodiment will be described.

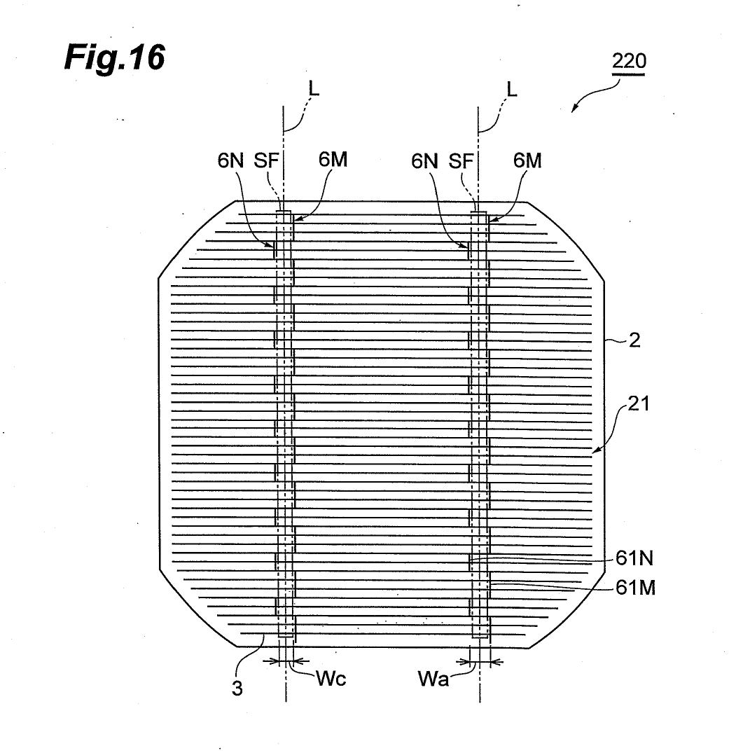

FIG. 16 is a plan view showing a front surface of the solar battery cell according to the thirteenth embodiment of the present invention. As shown in FIG. 16, a solar battery cell 220 according to the present embodiment is different from the solar battery cell 100 according to the first embodiment (see FIG. 1) in that light receiving surface alignment marks 6M and 6N are provided for one line L; each of the light receiving surface alignment marks 6M and 6N is different from the light receiving surface alignment mark 6A in the arrangement pattern of portions of the alignment mark.

The light receiving surface alignment marks 6M and 6N are provided for one line L. For example, the light receiving surface alignment marks 6M and 6N are provided on the right and left, respectively, of the line L. The width Wa between the light receiving surface alignment marks 6M and 6N is equal to or greater than the width We of the adhesion area SF (that is, the width of the conductive adhesion film 5). The light receiving surface alignment mark 6M has a pattern in which portions 61M of the light receiving surface alignment mark 6M are consecutively arranged along the line L; each of the portions 61M strides across a set of four adjacent finger electrodes 3 to 3 so as to connect two of the four finger electrodes 3 which are located at the opposite ends of the set. One finger electrode 3 not connected to any of the portions 61M is interposed between the consecutive portions 61M and 61M. The light receiving surface alignment mark 6N has a pattern in which portions 61N of the light receiving surface alignment mark 6N are consecutively arranged along the line L; each of the portions 61N strides across a set of three adjacent finger electrodes 3 to 3 so as to connect two of the three finger electrodes 3 which are located at the opposite ends of the set. Two finger electrodes 3 not connected to any of the portions 61N are interposed between the consecutive portions 61N and 61N. Furthermore, in the light receiving surface alignment marks 6M and 6N provided on the right and left, respectively, of the line L, the portions 61M of the light receiving surface alignment marks 6M are staggered with respect to the portions 61N of the light receiving surface alignment mark 6N. Thus, the light receiving surface alignment marks 6M and 6N are staggered with respect to each other. Additionally, since the portions 61M and 61N each striding across the plurality of finger electrodes 3, 3 are arranged in a staggered manner, all the finger electrodes 3 are coupled together by the light receiving surface alignment marks 6M and 6N.

Of course, the solar battery cell 220 configured as described above exerts effects similar to those of the solar battery cell 100 according to the first embodiment.

Furthermore, in the solar battery cell 220, since the plurality of light receiving surface alignment marks 6M and 6N are provided for the one line L, the alignment marks can be more easily visually identified, allowing the TAB wire 4 to be accurately connected to the intended position.

Additionally, in the solar battery cell 220, the width Wa between the plurality of light receiving surface alignment marks 6M and 6N provided for the one line L is equal to or greater than the width We of the conductive adhesion film 5. Thus, the conductive adhesion film 5 may be applied to between the light receiving surface alignment marks 6M and 6N so that the light receiving surface alignment marks 6M and 6N can be visually identified after the application of the conductive adhesion film 5. Hence, the TAB wire 4 can be more accurately connected to the intended position.

In addition, in the solar battery cell 220, the plurality of light receiving surface alignment marks 6M and 6N provided for the one line L are staggered with respect to each other. Thus, the alignment marks can be more easily visually identified, allowing the TAB wire 4 to be accurately connected to the intended position.

Furthermore, in the solar battery cell 220, since the portions 61M and 61N each striding across the plurality of adjacent finger electrodes 3 are arranged in a staggered manner, all the finger electrodes 3 are coupled together by the light receiving surface alignment marks 6M and 6N. The thus configured light receiving surface alignment marks 6M and 6N contribute to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to a fourteenth embodiment of the present invention will be described. Mainly differences of the present embodiment from the first embodiment will be described.

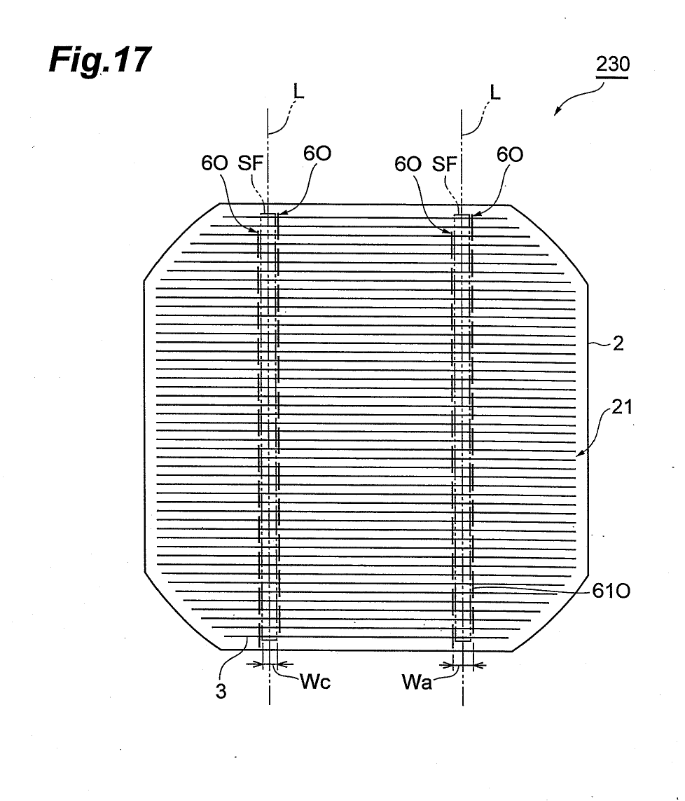

FIG. 17 is a plan view showing a front surface of the solar battery cell according to the fourteenth embodiment of the present invention. As shown in FIG. 17, a solar battery cell 230 according to the present embodiment is different from the solar battery cell 100 according to the first embodiment (see FIG. 1) in that a plurality of light receiving surface alignment marks 6O are provided for one line L; each of the light receiving surface alignment marks 6O is different from the light receiving surface alignment mark 6A in the arrangement pattern of portions of the alignment mark.

A plurality of (for example, two) light receiving surface alignment marks 6O are provided for one line L. For example, the light receiving surface alignment marks 6O are provided on the right and left, respectively, of the line L. The width Wa between the light receiving surface alignment marks 6O and 6O is equal to or greater than the width We of the adhesion area SF (that is, the width of the conductive adhesion film 5). The light receiving surface alignment mark 6O has a pattern in which portions 61O of the light receiving surface alignment mark 6O are consecutively arranged along the line L;

each of the portions 61O strides across a set of three adjacent finger electrodes 3 to 3 so as to cross the finger electrodes 3 to 3. One finger electrode 3 not connected to any of the portions 61O is interposed between the consecutive portions 61O and 61O. Furthermore, in the light receiving surface alignment marks 6O and 6O provided on the right and left, respectively, of the line L, the right-sided portions 61O are staggered with respect to the left-sided portions 61O and the light receiving surface alignment marks 6O and 6O are staggered with respect to each other. Additionally, since the portions 61O each striding across the three adjacent finger electrodes 3 to 3 are arranged in a staggered manner, all the finger electrodes 3 are coupled together by the light receiving surface alignment marks 6O, 6O.

Of course, the solar battery cell 230 configured as described above exerts effects similar to those of the solar battery cell 100 according to the first embodiment.

Furthermore, in the solar battery cell 230, since the plurality of (for example, two) light receiving surface alignment marks 6O are provided for the one line L, the alignment marks can be more easily visually identified, allowing the TAB wire 4 to be accurately connected to the intended position.

Additionally, in the solar battery cell 230, the width Wa between the plurality of (for example, two) light receiving surface alignment marks 6O and 6O provided for the one line L is equal to or greater than the width We of the conductive adhesion film 5. Thus, the conductive adhesion film 5 may be applied to between the light receiving surface alignment marks 6O and 6O so that the light receiving surface alignment marks 6O, 6O can be visually identified after the application of the conductive adhesion film 5. Hence, the TAB wire 4 can be more accurately connected to the intended position.

In addition, in the solar battery cell 230, the plurality of light receiving surface alignment marks 6O and 6O provided for the one line L are staggered with respect to each other. Thus, the alignment marks can be more easily visually identified, allowing the TAB wire 4 to be accurately connected to the intended position.

Furthermore, in the solar battery cell 230, since the portions 61O each striding across the three adjacent finger electrodes 3 to 3 are arranged in a staggered manner, all the finger electrodes 3 are coupled together by the light receiving surface alignment marks 6O, 6O. The thus configured light receiving surface alignment marks 6O contribute to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to a fifteenth embodiment of the present invention will be described. Mainly differences of the present embodiment from the first embodiment will be described.

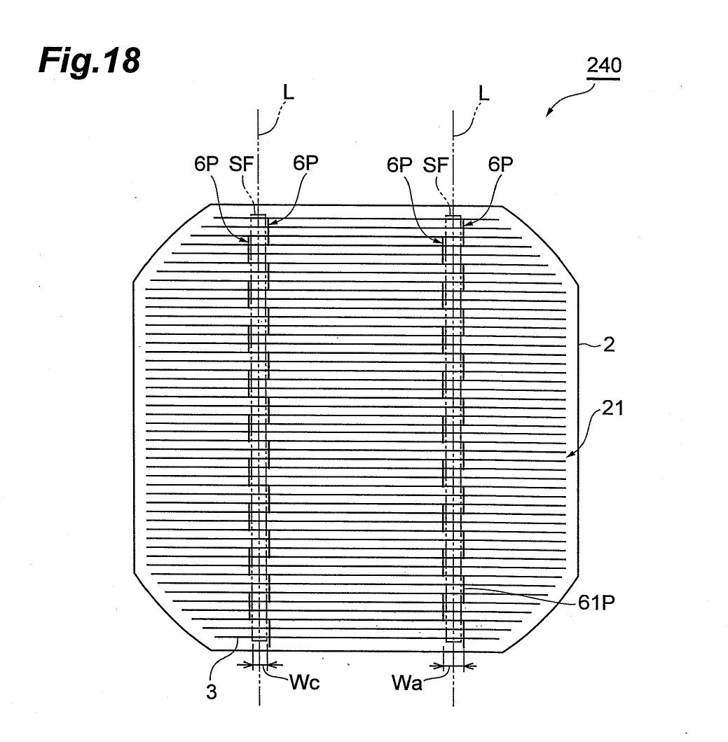

FIG. 18 is a plan view showing a front surface of the solar battery cell according to the fifteenth embodiment of the present invention. As shown in FIG. 18, a solar battery cell 240 according to the present embodiment is different from the solar battery cell 100 according to the first embodiment (see FIG. 1) in that a plurality of light receiving surface alignment marks 6P are provided for one line L; each of the light receiving surface alignment marks 6P is different from the light receiving surface alignment mark 6A in the arrangement pattern of portions of the alignment mark.

A plurality of (for example, two) light receiving surface alignment marks 6P are provided for one line L. For example, the light receiving surface alignment marks 6P are provided on the right and left, respectively, of the line L. The width Wa between the light receiving surface alignment marks 6P and 6P is equal to or greater than the width We of the adhesion area SF (that is, the width of the conductive adhesion film 5). The light receiving surface alignment mark 6P has a pattern in which portions 61P of the light receiving surface alignment mark 6P are consecutively arranged along the line L; each of the portions 61P strides across a set of three adjacent finger electrodes 3 to 3 so as to connect two of the three finger electrodes 3 which are located at the opposite ends of the set. One finger electrode 3 not connected to any of the portions 61P is interposed between the consecutive portions 61P and 61P. Furthermore, in the light receiving surface alignment marks 6P and 6P provided on the right and left, respectively, of the line L, the right-sided portions 61P are staggered with respect to the left-sided portions 61P and the light receiving surface alignment marks 6P and 6P are staggered with respect to each other. Additionally, since the portions 61P each striding across the three adjacent finger electrodes 3 to 3 are arranged in a staggered manner, all the finger electrodes 3 are coupled together by the light receiving surface alignment marks 6P, 6P.

Of course, the solar battery cell 240 configured as described above exerts effects similar to those of the solar battery cell 100 according to the first embodiment.

Furthermore, in the solar battery cell 240, since the plurality of (for example, two) light receiving surface alignment marks 6P are provided for the one line L, the alignment marks can be more easily visually identified, allowing the TAB wire 4 to be accurately connected to the intended position.

Additionally, in the solar battery cell 240, the width Wa between the plurality of (for example, two) light receiving surface alignment marks 6P and 6P provided for the one line L is equal to or greater than the width We of the conductive adhesion film 5. Thus, the conductive adhesion film 5 may be applied to between the light receiving surface alignment marks 6P and 6P so that the light receiving surface alignment marks 6P, 6P can be visually identified after the application of the conductive adhesion film 5. Hence, the TAB wire 4 can be more accurately connected to the intended position.

In addition, in the solar battery cell 240, the plurality of light receiving surface alignment marks 6P and 6P provided for the one line L are staggered with respect to each other. Thus, the alignment marks can be more easily visually identified, allowing the TAB wire 4 to be accurately connected to the intended position.

Furthermore, in the solar battery cell 240, since the portions 61P each striding across the three adjacent finger electrodes 3 to 3 are arranged in a staggered manner, all the finger electrodes 3 are coupled together by the light receiving surface alignment marks 6P, 6P. The thus configured light receiving surface alignment marks 6P contribute to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to a sixteenth embodiment of the present invention will be described. Mainly differences of the present embodiment from the first embodiment will be described.

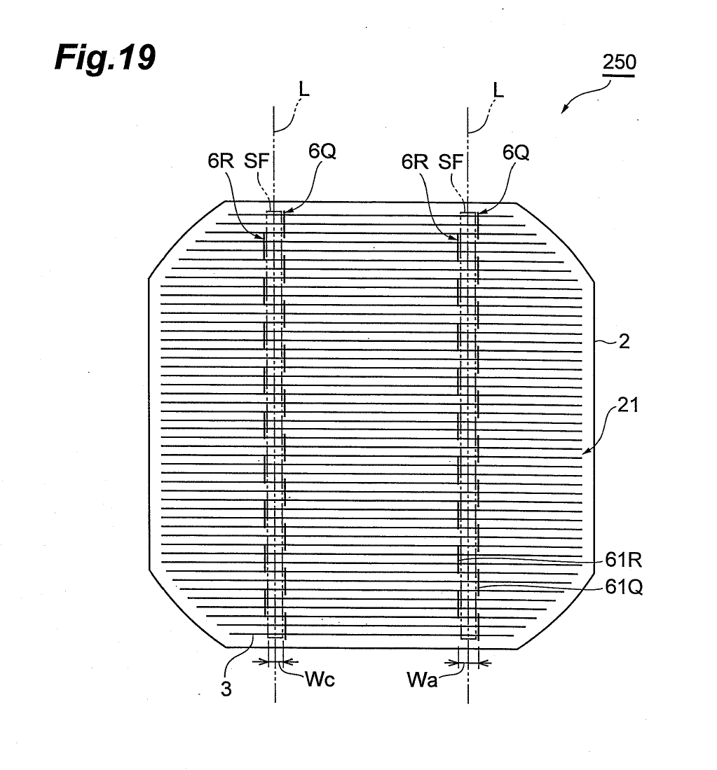

FIG. 19 is a plan view showing a front surface of the solar battery cell according to the sixteenth embodiment of the present invention. As shown in FIG. 19, a solar battery cell 250 according to the present embodiment is different from the solar battery cell 100 according to the first embodiment (see FIG. 1) in that light receiving surface alignment marks 6Q and 6R are provided for one line L; each of the light receiving surface alignment marks 6Q and 6R is different from the light receiving surface alignment mark 6A in the arrangement pattern of portions of the alignment mark.

Light receiving surface alignment marks 6Q and 6R are provided for one line L. For example, the light receiving surface alignment marks 6Q and 6R are provided on the right and left, respectively, of the line L. The width Wa between the light receiving surface alignment marks 6Q and 6R is equal to or greater than the width We of the adhesion area SF (that is, the width of the conductive adhesion film 5). The light receiving surface alignment mark 6Q has a pattern in which portions 61Q of the light receiving surface alignment mark 6Q are consecutively arranged along the line L; each of the portions 61Q strides across a set of three adjacent finger electrodes 3 to 3 so as to cross the finger electrodes 3 to 3. Two finger electrodes 3 not connected to any of the portions 61Q are interposed between the consecutive portions 61Q and 61Q. The light receiving surface alignment mark 6R has a pattern in which portions 61R of the light receiving surface alignment mark 6R are consecutively arranged along the line L; each of the portions 61R strides across a set of four adjacent finger electrodes 3 to 3 so as to connect two of the four finger electrodes 3 which are located at the opposite ends of the set. One finger electrode 3 not connected to any of the portions 61R is interposed between the consecutive portions 61R and 61R. Furthermore, in the light receiving surface alignment marks 6Q and 6R provided on the right and left, respectively, of the line L, the portions 61Q are staggered with respect to the portions 61R and the light receiving surface alignment marks 6Q and 6R are staggered with respect to each other. Additionally, since the portions 61Q and 61R each striding across the plurality of electrodes 3 to 3 are arranged in a staggered manner, all the finger electrodes 3 are coupled together by the light receiving surface alignment marks 6Q and 6R.

Of course, the solar battery cell 250 configured as described above exerts effects similar to those of the solar battery cell 100 according to the first embodiment.

Furthermore, in the solar battery cell 250, since the plurality of light receiving surface alignment marks 6Q and 6R are provided for the one line L, the alignment marks can be more easily visually identified, allowing the TAB wire 4 to be accurately connected to the intended position.

Additionally, in the solar battery cell 250, the width Wa between the plurality of light receiving surface alignment marks 6Q and 6R provided for the one line L is equal to or greater than the width We of the conductive adhesion film 5. Thus, the conductive adhesion film 5 may be applied to between the light receiving surface alignment marks 6Q and 6R so that the light receiving surface alignment marks 6Q and 6R can be visually identified after the application of the conductive adhesion film 5. Hence, the TAB wire 4 can be more accurately connected to the intended position.

In addition, in the solar battery cell 250, the plurality of light receiving surface alignment marks 6Q and 6R provided for the one line L are staggered with respect to each other. Thus, the alignment marks can be more easily visually identified, allowing the TAB wire 4 to be accurately connected to the intended position.

Furthermore, in the solar battery cell 250, since the portions 61Q and 61R each striding across the plurality of adjacent finger electrodes 3 are arranged in a staggered manner, all the finger electrodes 3 are coupled together by the light receiving surface alignment marks 6Q and 6R. The thus configured light receiving surface alignment marks 6Q and 6R contribute to simplifying the inspection of the finger electrodes 3 for disconnection or the like. That is, in such a configuration, all the finger electrodes 3 form one mass. Thus, when an inspection probe comes into contact with the mass, all the finger electrodes 3 can be inspected at a time. Hence, the number of probes required for the inspection can be reduced, enabling a reduction in inspection costs.

Now, a solar battery cell according to a seventeenth embodiment of the present invention will be described. Mainly differences of the present embodiment from the first embodiment will be described.

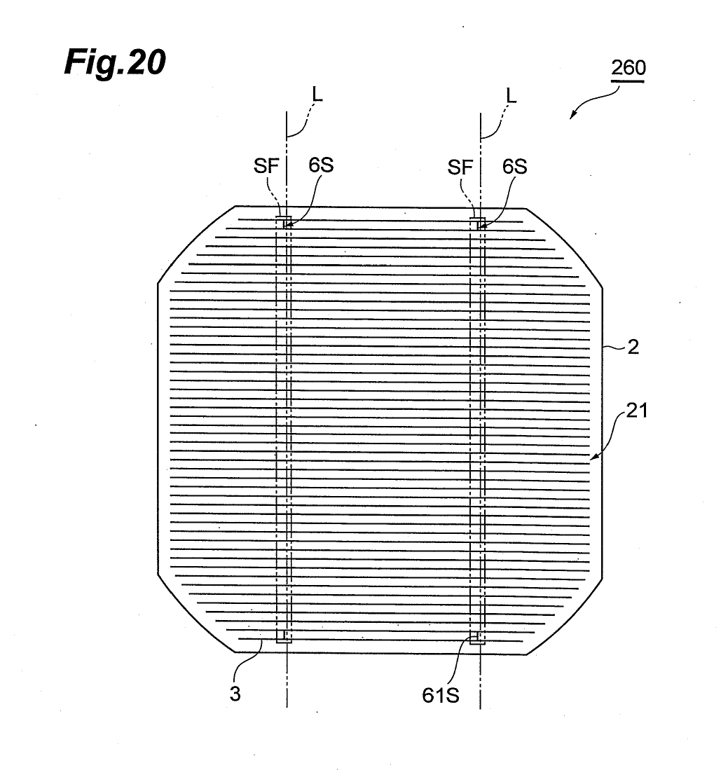

FIG. 20 is a plan view showing a front surface of the solar battery cell according to the seventeenth embodiment of the present invention. As shown in FIG. 20, a solar battery cell 260 according to the present embodiment is different from the solar battery cell 100 according to the first embodiment (see FIG. 1) in that the solar battery cell 260 includes light receiving surface alignment marks 6S each with portions 61S provided at the opposite ends of the light receiving surface and each connecting the finger electrode 3 positioned at the end of the set of all the finger electrodes 3 and the finger electrode 3 adjacent to the finger electrode 3 positioned at the end of the set.

Of course, the solar battery cell 260 configured as described above exerts effects similar to those of the solar battery cell 100 according to the first embodiment.

Furthermore, in the solar battery cell 260, the light receiving surface alignment mark 6S includes the portions 61S each connecting the finger electrode 3 positioned at the end of the set of all the finger electrodes 3 and the finger electrode 3 adjacent to the finger electrode 3 positioned at the end of the set. Thus, a possible increase in the usage of the electrode material can be further suppressed, enabling a possible increase in manufacturing costs to be restrained.

As will be appreciated from the foregoing description, a solar battery cell according to the invention can be made by a method including: providing a photovoltaic substrate having a plurality of finger electrodes arranged on a light receiving surface thereof, the light receiving surface having a region of predetermined width to receive a conductive adhesive of a same width as the region; and providing, at or adjacent to the region an alignment marking indicating a position where a TAB wire is to be connected to the finger electrodes via the conductive adhesive, the alignment marking having portions discontinuously provided on the light receiving surface along a line crossing two of the finger electrodes positioned nearest opposite ends of the light receiving surface, the alignment marking being provided either before or after the plurality of finger electrodes are formed on the light receiving surface.

Further, a solar battery module of the invention can be made by a method that includes: 1) providing a plurality of the solar battery cells according to the invention; 2) positioning the TAB wire along the alignment marking on one of the plurality of solar battery cells and connecting the TAB wire to the finger electrodes of said one solar battery cell via the conductive adhesive; and 3) connecting the TAB wire to a back surface electrode formed on a back surface of another of the plurality of solar battery cells; wherein steps 2) and 3 may be performed in either order.

The preferred embodiments of the solar battery cells according to the present invention have been described in detail. However, the present invention is not limited to the above-described embodiments. For example, in the above-described embodiments, the back surface electrode 7 is connected to the TAB wire 4 via the conductive adhesion film 5. However, a bus bar electrode formed of Ag or the like may be provided at the position on the back surface electrode 7 to which the TAB wire 4 is to be connected so that the back surface electrode 7 and the TAB wire 4 can be electrically connected together by connecting the bus bar electrode to the TAB wire 4 by solder.

Furthermore, in the above-described embodiments, the film-like conductive adhesion film 5 is used as the conductive adhesive. However, a liquid conductive adhesive may be applied.

In the above-described embodiments, the light receiving surface alignment marking can be formed of a different material from that of the finger electrodes. As a material for the light receiving surface alignment marking, for example, manufacturing costs can be suppressed by employing an inexpensive material than the material for the finger electrodes. It should be noted that the different material includes materials comprising different components or the same components in a different content rate.

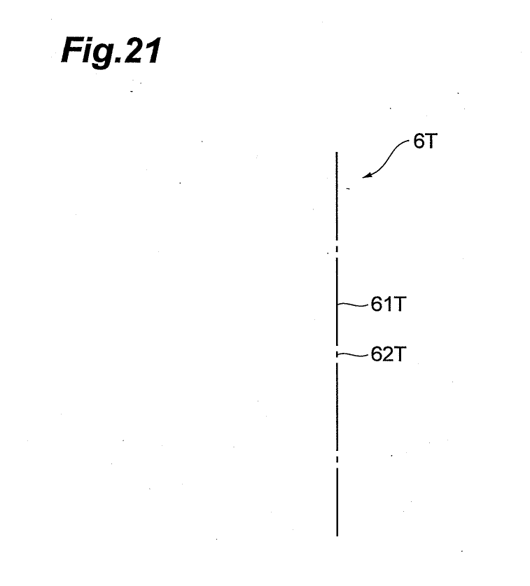

Also, in the above-described embodiments, as the light receiving surface alignment marking, for example, such a form shown by FIG. 21 may be employed. The light receiving surface alignment marking 6T shown by FIG. 21 is a dashed line forming a pattern in which portion 61T and portion 62T, the length along line L of which is shorter than portion 61T, are positioned in an alternating sequence. It should be noted that a plurality of portions 61T may be positioned consecutively and a plurality of portions 62T may be positioned consecutively.

Furthermore, in the above-described embodiments, as the solar battery cell, especially, those with a single crystalline silicon substrate, those with a polycrystalline silicon substrate, or those with a substrate in which a single crystalline silicon is laminated with an amorphous silicon (for example, HIT series manufactured by Panasonic Corporation) are preferable.

Also, in the above-described embodiments, materials for the finger electrodes, other than the above-described materials, include materials such as glass paste containing aluminum, glass paste containing copper, and glass paste containing an alloy comprising at least one of silver, aluminum, and copper. The same applies to the materials for the light receiving surface alignment markings in the above-described embodiments.

Moreover, in the above-described embodiments, the line width of each portion of the light receiving surface alignment marking, even more preferably, is at least 0.10 mm and at most 0.18 mm.

Also, in the above-described embodiments, even though the number of the adhesion areas SF (the number of TAB wires) is described as 2, it may be other numbers (for example, 3 to 5).

Furthermore, the number of the finger electrodes over which each light receiving surface alignment marking portion crosses is preferably 2 or more, more preferably, 2 or more and not more than 20, and even more preferably, 2 or more and not more than 10. In addition, the number of the finger electrodes on which each portion of the light receiving alignment marking crosses need not be the same at every portion but can be different by each portion.

Also, the forger electrodes need not be linear.

1. A solar battery cell comprising:
a plurality of finger electrodes arranged on a light receiving surface of a photovoltaic substrate; and
an alignment marking indicating a position where a TAB wire is to be connected to the finger electrodes via a conductive adhesive, the alignment marking having portions discontinuously provided on the light receiving surface along a line crossing two of the finger electrodes positioned nearest opposite ends of the light receiving surface.

2. The solar battery cell of claim 1, wherein:
each alignment marking portion is formed of .a material identical to a material of the finger electrodes, each alignment marking portion further having a line width equal to or smaller than a line width of the TAB wire.

3. The solar battery cell of claim 1, wherein:
each alignment marking portion is formed of a material different from the material of the finger electrodes, each alignment marking portion further having a line width equal to or smaller than a line width of the TAB wire.

4. The solar battery cell of claim 2, wherein:
each alignment marking portion is integral with at least a corresponding one of the finger electrodes.

5. The solar battery cell of claim 1, wherein said alignment marking is discontinuous in a direction generally parallel to said line crossing said two of the finger electrodes.

6. The solar battery cell of claim 1, wherein said alignment marking is discontinuous in a direction generally perpendicular to said line crossing said two of the finger electrodes.

7. The solar battery cell according to claim 1, wherein the alignment marking includes a dashed line.

8. The solar battery cell according to claim 1, wherein each portion of the alignment marking intersects a plurality of the finger electrodes.

9. The solar battery cell according to claim 1, wherein the alignment marking comprises a plurality of elongated linear portions positioned along a single straight line.

10. The solar battery cell according to claim 1, wherein the alignment marking includes portions which are staggered with respect to one another.

11. The solar battery cell according to claim 1, wherein the alignment marking portions define a region having a width equal to or greater than a width of the conductive adhesive.

12. The solar battery cell according to claim 1, wherein each portion of the alignment marking has a width equal to or smaller than a width of one of said finger electrodes.

13. The solar battery cell according to claim 1, wherein each portion of the alignment marking has a width of at least 0.05 mm and at most 0.2 mm.

14. A solar battery module comprising:
a plurality of the solar battery cells according to claim 1, wherein:
the TAB wire is positioned along the alignment marking on one of the plurality of solar battery cells and is connected to the finger electrodes of said one solar battery cell via said conductive adhesive, and
the TAB wire is further connected to a back surface electrode formed on a back surface of another of the plurality of solar battery cells.

15. A method of making a solar battery cell, comprising:
providing a photovoltaic substrate having a plurality of finger electrodes arranged on a light receiving surface thereof, said light receiving surface having a region of predetermined width to receive a conductive adhesive of a same width as said region; and
providing, at or adjacent to said region, an alignment marking indicating a position where a TAB wire is to be connected to the finger electrodes via the conductive adhesive, the alignment marking having portions discontinuously provided on the light receiving surface along a line crossing two of the finger electrodes positioned nearest opposite ends of the light receiving surface, the alignment marking being provided either before or after the plurality of finger electrodes are formed on the light receiving surface.

16. The method of claim 15, wherein:
each alignment marking portion is formed of a material identical to a material of the finger electrodes, each alignment marking portion further having a line width equal to or smaller than a line width of the TAB wire.

17. The method of claim 15, wherein:
each alignment marking portion is formed of a material different from the material of the finger electrodes, each alignment marking portion further having a line width equal to or smaller than a line width of the TAB wire.

18. The method of claim 16, wherein:
each alignment marking portion is integral with at least a corresponding one of the finger electrodes.

19. The method of claim 15, wherein said alignment marking is discontinuous in a direction generally parallel to said line crossing said two of the finger electrodes.

20. The method of claim 15, wherein said alignment marking is discontinuous in a direction generally perpendicular to said line crossing said two of the finger electrodes.

21. The method of claim 15, wherein the alignment marking is a dashed line.

22. The method of claim 15, wherein each portion of the alignment marking intersects a plurality of the finger electrodes.

23. The method of claim 15, wherein the alignment marking comprises a plurality of elongated linear portions positioned along a single straight line.

24. The method of claim 15, wherein the alignment marking portions are staggered with respect to one another.

25. The method of claim 15, wherein the alignment marking portions define a region having a width equal to or greater than a width of the conductive adhesive.

26. The method of claim 15, wherein each portion of the alignment marking has a width equal to or smaller than a width of one of said finger electrodes.

27. The method of claim 15, wherein each portion of the alignment marking has a width of at least 0.05 mm and at most 0.2 mm.

28. A method of making a solar battery module, comprising the steps of:
1) providing a plurality of the solar battery cells according to claim 1;
2) positioning the TAB wire along the alignment marking on one of the plurality of solar battery cells and connecting the TAB wire to the finger electrodes of said one solar battery cell via said conductive adhesive; and
3) connecting the TAB wire to a back surface electrode formed on a back surface of another of the plurality of solar battery cells;
steps 2) and 3 being performed in either order.
